(19) United States
(12) Patent Application Publication
(10) Pub. No.: US 2025/0239991 A1
(43) Pub. Date: Jul. 24, 2025

(54) MULTI-PIEZO ACOUSTIC WAVE DEVICES

(71) Applicant: Qorvo US, Inc., Greensboro, NC (US)

(72) Inventors: Mayur Bhushan Birla, Apopka, FL (US); Seyed Amin Sandoughsaz Zardini, Sanford, FL (US); Chanseob Cho, Allen, TX (US); Andreas Tag, Geretsried (DE); Jaime Gerardo Trujillo, McKinney, TX (US)

(21) Appl. No.: 18/417,166

(22) Filed: Jan. 19, 2024

(51) Int. Cl. H03H 9/205; H03H 3/02; H03H 9/02; H03H 9/17

(52) U.S. Cl. CPC H03H 9/205; H03H 3/02; H03H 9/02031; H03H 9/175; H03H 9/176; H03H 2003/025

(57) ABSTRACT

One aspect of the present disclosure pertains to a method of forming an acoustic wave device. The method includes forming a reflector stack structure over a substrate, forming a bottom electrode over the reflector stack structure, depositing a first piezoelectric layer over the bottom electrode, patterning the first piezoelectric layer to form a trench exposing a top surface of the bottom electrode and a sloped side surface of the patterned first piezoelectric layer, depositing a second piezoelectric layer in the trench and over the exposed top surface of the bottom electrode and over the first piezoelectric layer, and patterning the second piezoelectric layer to remove portions of the second piezoelectric layer not within the trench.

### FIELD OF THE DISCLOSURE

The present disclosure relates to multi-piezo acoustic wave devices and a process for making the same, and more particularly, to forming a smooth interface between adjacent piezoelectric layers for different resonators on a same die.

### BACKGROUND

Acoustic wave devices have incorporated multi-piezo film stacks for improved performance. For example, multiple piezo films are stacked on top of each other (Z-dimension) in bulk acoustic wave (BAW) devices in various applications. Further, filters and resonators having different piezoelectric materials may be formed and assembled on different dies for different tailored applications. However, to meet the ever-growing need to scale down acoustic wave devices while improving performance, further process developments are needed.

One area of improvement is to form resonators with different piezoelectric materials on a same die, which offers tremendous size and performance advantages. However, this has proved difficult due to process and variation concerns. For example, existing device and methods may require tradeoff between better cycle time (production time) versus smaller variation of critical electrical parameters. As such, high volume manufacturing to enable growth of different piezoelectric layers next to each other has been challenging. Accordingly, there is a need for a multi-piezo device structure and a manufacturing method compatible with high volume manufacturing without degrading the die-to-die variation on filter performance and critical electrical parameters.

### SUMMARY

The present disclosure relates to multi-piezo acoustic wave devices and a process for making the same. More particularly, the present disclosure relates to forming different piezoelectric materials on a same die, for example, by using a sacrificial etch stop layer and an optimized layout design. The formation process creates a smooth topology interface between the different piezoelectric materials. Further, the process creates a substantially level top surface between the different piezoelectric material layers.

In one aspect, the present disclosure pertains to a method of forming an acoustic wave device. The method includes forming a reflector stack structure over a substrate, forming a bottom electrode over the reflector stack structure, depositing a first piezoelectric layer over the bottom electrode, patterning the first piezoelectric layer to form a trench exposing a top surface of the bottom electrode and a sloped side surface of the patterned first piezoelectric layer, depositing a second piezoelectric layer in the trench and over the exposed top surface of the bottom electrode and over the first piezoelectric layer, and patterning the second piezoelectric layer to remove portions of the second piezoelectric layer not within the trench.

In another aspect, the present disclosure pertains to a method of forming an acoustic wave device. The method includes forming a reflector stack structure over a substrate, forming first and second bottom electrodes over the reflector stack structure where the first and second bottom electrodes are separated by an isolation structure. The method further includes depositing a first piezoelectric layer over the first and the second bottom electrodes, depositing a sacrificial etch stop layer over the first piezoelectric layer, selectively etching the first piezoelectric layer by etching through the etch stop layer to form a trench exposing a top surface of the second bottom electrode, depositing a second piezoelectric layer in the trench and over remaining portions of the sacrificial etch stop layer, and selectively etching the second piezoelectric layer by etching portions of the second piezoelectric layer over the remaining portions of the sacrificial etch stop layer.

In another aspect, the present disclosure pertains to an acoustic wave device. The acoustic wave device includes a reflector stack structure over a substrate, a bottom electrode over the reflector stack structure, a first piezoelectric layer landing on a first portion of the bottom electrode, and a second piezoelectric layer landing on a second portion of the bottom electrode. The first piezoelectric layer and the second piezoelectric layer include different piezoelectric materials. The first piezoelectric layer and the second piezoelectric layer are laterally adjacent to each other and share a sloped interface.

Those skilled in the art will appreciate the scope of the present disclosure and realize additional aspects thereof after reading the following detailed description of the preferred embodiments in association with the accompanying figures.

### BRIEF DESCRIPTION OF THE FIGURES

The accompanying figures incorporated herein and forming a part of this specification illustrate several aspects of the disclosure, and together with the description, serve to explain the principles of the disclosure.

FIG. 1A illustrates an acoustic wave device having resonators formed side by side with different piezoelectric materials, according to an embodiment of the present disclosure.

FIG. 1B illustrates an acoustic wave device having resonators formed side by side with different piezoelectric materials, according to another embodiment of the present disclosure.

FIG. 2 illustrates a flow chart of a method to form an acoustic wave device having resonators side by side with different piezoelectric materials, in portion or in entirety, according to an embodiment of the present disclosure.

FIGS. 3-9 illustrate an acoustic wave device at intermediate stages of fabrication and processed in accordance with the method of FIG. 2, according to an embodiment of the present disclosure.

FIGS. 10A-10C illustrate various height configurations of piezoelectric layers adjacent to each other, according to various embodiments of the present disclosure.

It will be understood that for clear illustrations, the drawings may not be drawn to scale. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

When a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 mm” may encompass the dimension range from 4.5 mm to 5.5 mm. And when comparing a dimension or size of a feature to another feature, the phrases “substantially the same,” “essentially the same,” “of similar size,” and the like, are understood to be within +/−10% between the compared features. Further, disclosed dimensions of the different features can implicitly disclose dimension ratios between the different features.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The present disclosure relates to multi-piezo acoustic wave devices having resonators (or filters) formed side by side, where each resonator is formed on a same die and with different piezoelectric materials. The integration of different piezoelectric materials allows for improved optimization by tuning each resonator to maximize overall performance. For example, one resonator has a piezo layer made of aluminum nitride (AlN) to achieve high Q factor for steeper filter curves, while an adjacent resonator has a piezo layer made of scandium aluminum nitride (e.g., Al_{0.8}Sc_{0.2}N) to achieve high electromechanical coupling for a wider band filter. Integrating the different piezo layers with a smooth topology results in an acoustic wave device having both improved Q factor and coupling bandwidth.

The method and structure described herein may generally apply to piezoelectric devices (i.e., devices having piezoelectric materials). For illustrative purposes, the embodiments in the present disclosure are implemented with bulk acoustic wave (BAW) devices (such as solidly mounted resonator (SMR) BAW devices or film bulk acoustic resonator (FBAR) BAW devices), but the present disclosure is not limited thereto. For example, the method and structure described herein may equally apply to other piezoelectric devices or acoustic wave devices such as surface acoustic wave (SAW) devices, temperature-compensated (TC) SAW devices, low-loss resonator technology (LRT) SAW devices, thin film (TF) SAW devices, incredibly high performance (IHP) SAW devices, and other layered SAW devices. Those of ordinary skill in the art should appreciate that they may readily use the present disclosure as a basis for designing or modifying other structures for carrying out the same purposes and/or achieving the same advantages of the embodiments introduced herein.

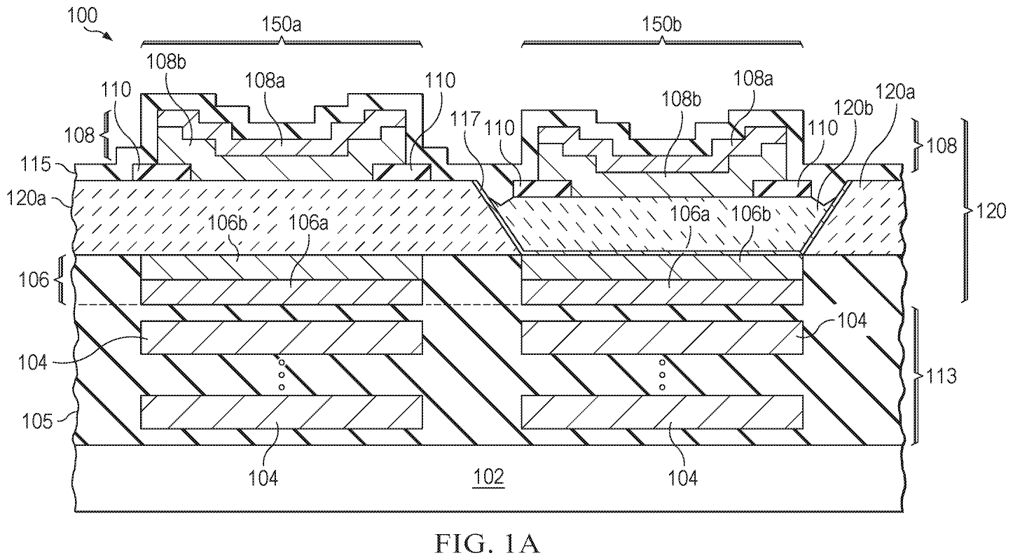

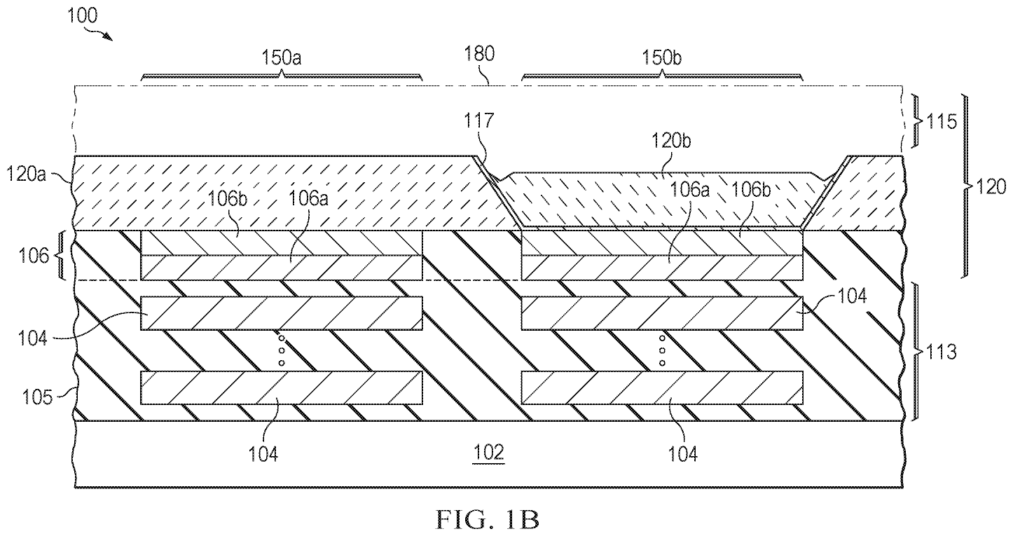

FIG. 1A illustrates an acoustic wave device 100 (e.g., a BAW device) having resonators 150a and 150b formed side by side. The resonators 150a and 150b include different piezoelectric materials (as shown by the different piezoelectric layers 120a and 120b). As shown, the acoustic wave device 100 includes a substrate 102, a reflector stack structure 113 over the substrate 102, a piezoelectric structure 120 over the reflector stack structure 113, and a passivation layer 115 over the piezoelectric structure 120. The substrate 102 may be a silicon substrate or a substrate having other semiconductor materials. In some embodiments, in lieu of or as part of the reflector stack structure 113, there includes an air layer or a cavity layer.

Still referring to FIG. 1A, the reflector stack structure 113 includes multiple vertically stacked metal layers 104. The metal layers 104 are isolated from each other by multiple intervening dielectric layers, which may be part of an isolation structure 105. In an embodiment, the metal layers 104 include tungsten (W) or other low impedance material, and the intervening dielectric layers (as part of the isolation structure 105) include silicon oxide, silicon oxynitride, fluorine-doped silicate glass (FSG), tetraethoxysilane (TEOS), a low-k dielectric, combinations thereof, and/or other suitable high impedance materials.

Still referring to FIG. 1A, the piezoelectric structure 120 includes bottom electrodes 106, piezoelectric layers 120a and 120b, and top electrodes 108. In an embodiment, the bottom electrodes 106 include similar materials as the metal layer 104. For example, the bottom electrodes 106 include tungsten. In the embodiment shown, the bottom electrodes 106 include a top electrode layer 106b over a bottom electrode layer 106a. The top electrode layer 106b may include tungsten, and the bottom electrode layer 106a may include aluminum copper (AlCu). The piezoelectric layers 120a and 120b are laterally disposed next to each other and include different piezoelectric materials. In the present embodiment, the piezoelectric layer 120a is formed as part of the resonator 150a and includes aluminum nitride (AlN), and the piezoelectric layer 120b is formed as part of the resonator 150b and includes scandium aluminum nitride (ScAlN). As shown, there is a sloped smooth interface between the piezoelectric layers 120a and 120b. The piezoelectric layer 120a may directly land on and contact the bottom electrodes 106. The piezoelectric layer 120b may be laterally surrounded by the piezoelectric layer 120a such that the piezoelectric layer 120b lands on bottom and side surfaces of the piezoelectric 120a (or a seed layer 117 thereof). To facilitate the sloped smooth interface topology, the piezoelectric layer 120a may have a top surface below a top surface of the piezoelectric layer 120b. The sloped smooth interface topology provides advantages such as simplified integration between different piezo materials, smooth passivation layer deposition over the dual piezo materials, and improved metal continuity. In an embodiment, the top electrodes 108 include similar materials as the metal layer 104. For example, the top electrodes 108 include tungsten. In another embodiment, the top electrodes 108 includes a top electrode layer 108a over a bottom electrode layer 108b. The top electrode layer 108a may include aluminum copper (AlCu), and the bottom electrode layer 108a may include tungsten.

Still referring to FIG. 1A, a passivation layer 115 is disposed over the piezoelectric structure 120, and specifically over a top surface of the top electrodes 108 and also over top surfaces of portions of the piezoelectric layers 120a and 120b. Due to the sloped interface topology, the passivation layer 115 makes good surface contact at the sloped interface between the piezoelectric layers 120a and 120b and avoids unwanted defects at the interface. The passivation layer is conformally disposed over both resonators 150a and 150b. In an embodiment, the passivation layer includes silicon nitride. Further, in the embodiment shown, dielectric features 110 may be separately formed over portions of the piezoelectric layer 120a and 120b to define an opening where the top electrodes 108 are formed. The dielectric features 110 may include silicon oxide and have a different material composition than from the passivation layer 115.

As shown in FIG. 1A, each of the resonators 150a and 150b have their own reflector stacks (see separate stacks of metal layers 104), bottom electrodes 106, and top electrodes 108. That is, the resonator 150a includes a first reflector stack with a first stack of metal layers 104 directly above a first portion of the substrate 102, a first bottom electrode 106 directly above the first stack of metal layers 104, a piezoelectric layer 120a directly above the first bottom electrode 106, and a first top electrode 108 directly above the piezoelectric layer 120a. And adjacent to the resonator 150a, the resonator 150b includes a second reflector stack with a second stack of metal layers 104 directly above a second portion of the substrate 102, a second bottom electrode 106 directly above the second stack of metal layers 104, a piezoelectric layer 120b directly above the second bottom electrode 106, and a second top electrode 108 directly above the piezoelectric layer 120b. The first and second stack of metal layers 104, bottom electrodes 106, and top electrodes 108 may be laterally isolated from each other by dielectric materials (e.g., by the isolation structure 105 and the passivation layer 115). On the other hand, the piezoelectric layers 120a and 120b are not isolated from each other and share common interfaces.

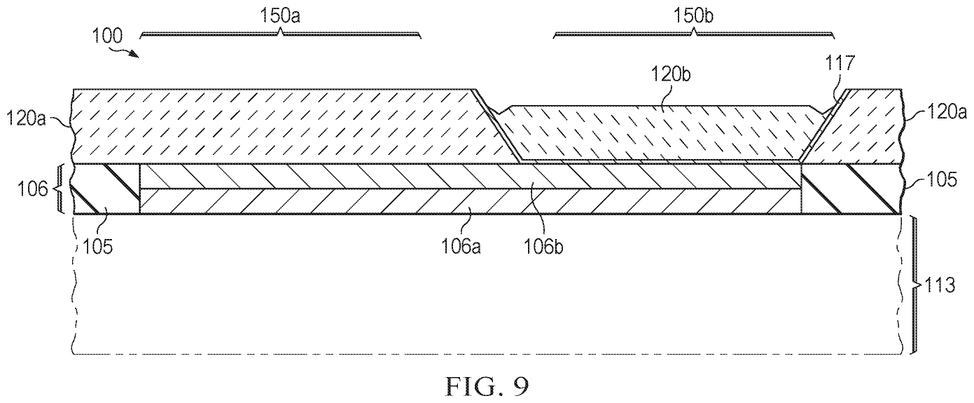

Still referring to FIG. 1A, in other embodiments (not shown here), the resonators 150a and 150b may share a reflector stack having metal layers 104 that continuously extend from the resonator 150a region to the resonator 150b region, a bottom electrode 106 that continuously extend from the resonator 150a region to the resonator 150b region, and/or a top electrode 108 that continuously extend from the resonator 150a region to the resonator 150b region. In these cases, the first and second piezoelectric layers 120a and 120b may land on different portions of a shared bottom electrode 106 (see FIG. 9).

FIG. 1B illustrates an acoustic wave device 100 resembling the one shown in FIG. 1A. The similar features will not be described again for the sake of brevity. The difference is that FIG. 1B is not restricted to the top electrode features described in FIG. 1A. Or more specifically, a different top structure 180 may be disposed over the first and second piezoelectric layers 120a and 120b. The top structure 180 may or may not contain other layers, such as a different type of top electrode (e.g., interdigital transducer (IDT) electrodes), another reflector stack, a packaging layer, a buffer layer, etc.

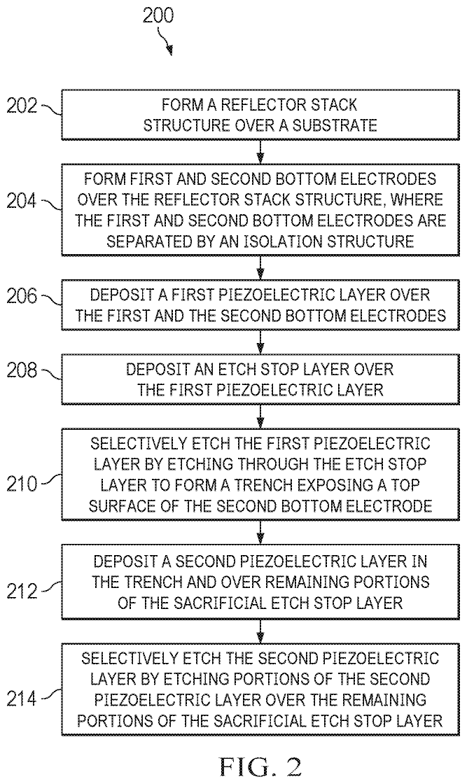

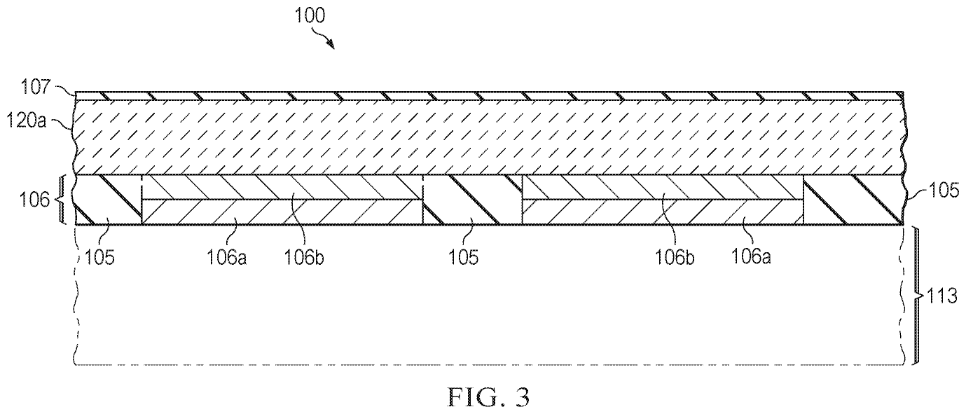

Additional details of the present disclosure, and specifically to the forming of the piezoelectric layers 120a and 120b, are described with respect to a method 200 in FIG. 2 and the intermediate structures in FIGS. 3-9. Note that features described in FIGS. 1A-1B may be referred to when describing FIGS. 3-9, and some of the features in FIGS. 1A-1B may be omitted in FIGS. 3-9 for the sake of brevity and simplifying drawings.

FIG. 2 illustrates a flow chart of a method 200 to form an acoustic wave device 100 having resonators 150a and 150b side by side with different piezoelectric materials, in portion or in entirety, according to an embodiment of the present disclosure. FIGS. 3-9 illustrate an acoustic wave device 100 at intermediate stages of fabrication and processed in accordance with the method 200 of FIG. 2.

Referring now to FIG. 3, the method 200 at operation 202 forms a reflector stack structure 113 over a substrate (e.g., substrate 102) by a suitable deposition process. The reflector stack structure 113 may correspond to those shown in FIGS. 1A-1B and will not be described again for the sake of brevity. Still referring to FIG. 3, the method 200 at operation 204 forms first (left) and second (right) bottom electrodes 106 over the reflector stack structure 113. The first (left) and second (right) bottom electrodes 106 are separated by an isolation structure 105. The first (left) and second (right) bottom electrodes 106 (which may each include a bottom electrode layer 106a and a top electrode layer 106b) may correspond to those shown in FIGS. 1A-1B and will not be described again for the sake of brevity. As shown, a top surface of the first (left) and second (right) bottom electrodes 106 and a top surface of the isolation structure 105 may be coplanar, for example, by performing a chemical planarization process (CMP).

Still referring to FIG. 3, the method 200 at operation 206 deposits a first piezoelectric layer 120a over the first (left) and the second (right) bottom electrodes 106. In the embodiment shown, the first piezoelectric layer 120a directly contacts and directly lands on top surfaces of the respective top electrode layers 106b and the isolation structure 105. As described previously, the first piezoelectric layer 120a includes a first piezo material. In the present embodiment, the first piezo material is AlN instead of ScAlN due to AlN having better surface contact properties for contacting the bottom electrodes 106. However, in other embodiments, the first piezo material may include ScAlN, or other piezoelectric materials such as lead zirconate titanate (PZT), barium titanate, lithium niobate, lithium titanate, and/or lithium tantalate (LT).

Still referring to FIG. 3, the method 200 at operation 208 deposits an etch stop layer 107 over the first piezoelectric layer 120a. In some embodiments, operation 208 is omitted and no etch stop layer is deposited. However, as described in more detail below, the etch stop layer 107 provides uniformity improvements due to providing etchant selectivity when selectively etching the second piezoelectric layer 120b. Note that the etch stop layer 107 is a sacrificial layer and will be completely removed in a later step. As such, there is freedom to utilize various materials for the etch stop layer 107, thereby improving process window. For example, the etch stop layer 107 may include a dielectric or a metal. In an embodiment, the etch stop layer 107 is a silicon oxide layer, a silicon nitride layer, or a tungsten layer.

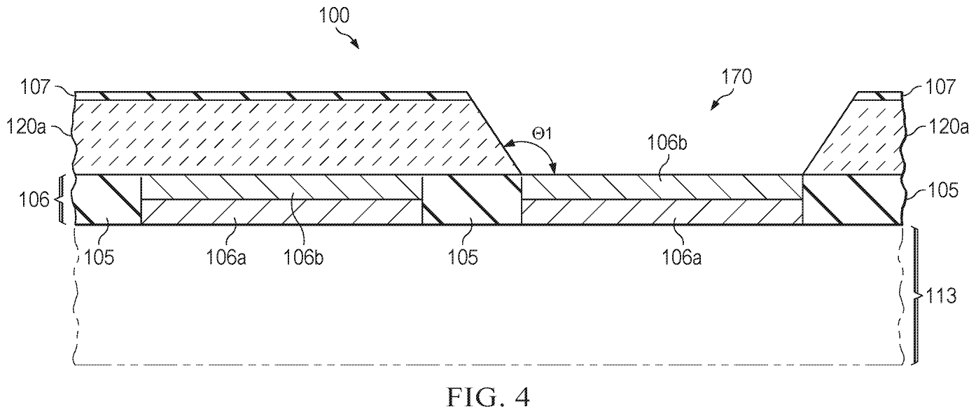

Referring now to FIG. 4, the method 200 at operation 210 selectively etches the first piezoelectric layer 120a through a patterning process. The selective etching includes etching through the etch stop layer 107 and the first piezoelectric layer 120a to form a trench 170 exposing a top surface of the second bottom electrode 106. The patterning process in operation 210 includes a lithography and/or etching process for patterning the first piezoelectric layer 120a. The etching process may include a dry etching process, a wet etching process, ion-milling, other suitable etching process, or combinations thereof. In some embodiments, the etching process is a reactive ion etching (RIE) process.

Still referring to FIG. 4, note that the trench 170 includes sloped side surfaces. The sloped side surfaces are intentional to define a smooth side surface interface in a later step between piezoelectric materials. The angle of the sloped side surfaces may be controlled by a specific lithography and/or etching process. The sloped side surfaces should not be too steep. If too steep, there results in unwanted humps and joints between piezoelectric materials when the later piezoelectric layer 120b is deposited. In an embodiment, an angle θ1 between a sloped side surface of the patterned first piezoelectric layer 120a and an exposed horizontal surface of the second bottom electrode 106 is greater than about 100 degrees. In an embodiment, the angle θ1 is not less than 90 degrees.

Still referring to FIG. 4, the etching process may completely expose the top surface of the second bottom electrode 106 and partially expose a top surface of the isolation structure 105. Note that the first bottom electrode 106 (left bottom electrode) remain covered by the first piezoelectric layer 120a. In the embodiment shown, the trench 170 exposes side surfaces of the patterned first piezoelectric layer 120a and side surfaces of the etch stop layer 107. Remaining portions of etch stop layer 107 are still disposed over top horizontal surfaces of the first piezoelectric layer 120a.

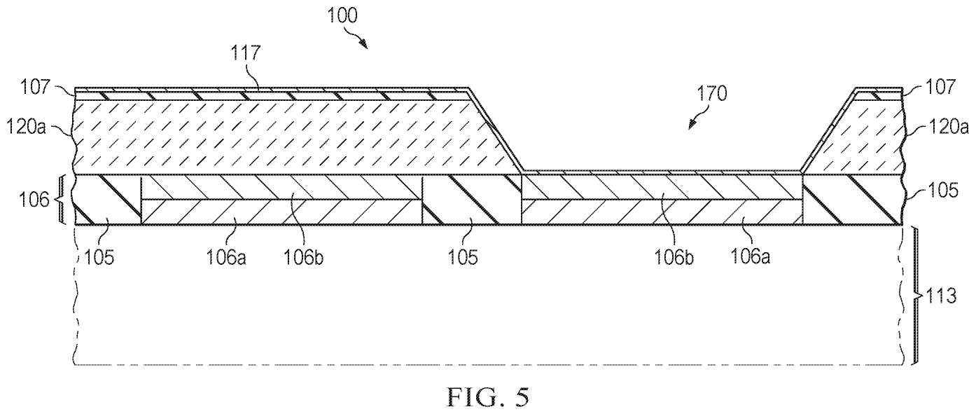

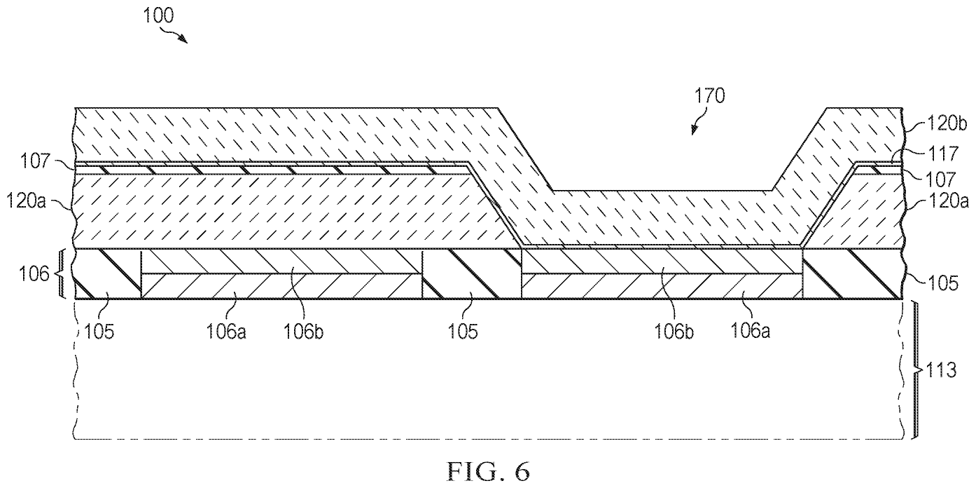

Referring now to FIGS. 5-6, the method 200 at operation 212 deposits a second piezoelectric layer 120b in the trench 170 and over remaining portions of the sacrificial etch stop layer 107. Referring to FIG. 5, operation 212 may include first depositing a seed layer 117 before depositing the second piezoelectric layer 120b. The seed layer 117 may provide better adhesion and interface to the top surface of the second bottom electrode 106 (right bottom electrode). In an embodiment, the seed layer 117 may include AlN. In another embodiment, to facilitate better adhesion, the seed layer 117 may include ScAlN, but the concentration of scandium in the seed layer 117 is less than the concentration of scandium in the second piezoelectric layer 120b. In another embodiment, the seed layer 117 may include a different material from both the first and the second piezoelectric layers 120a and 120b. In other embodiments, the step of depositing the seed layer 117 is omitted. Referring to FIG. 6, operation 212 deposits the second piezoelectric layer 120b over the seed layer 117. The second piezoelectric layer 120b is conformally deposited over both the resonator 150a region and the resonator 150b region (i.e., directly above both the first and second bottom electrodes 106). As described previously, the second piezoelectric layer 120b includes a second piezo material different from the first piezo material. In the present embodiment, the second piezo material is ScAlN having various scandium concentrations. For example, the scandium concentration in the second piezo material may range from 6 percent to over 40 percent, with a chemical formula of AlₓSc₁₋ₓN. In one embodiment, the scandium concentration may be at 20% with a chemical formula of Al_{0.8}Sc_{0.2}N. However, in other embodiments, the second piezo material may be AlN (when the first piezo material is ScAlN), or other piezoelectric materials such as lead zirconate titanate (PZT), barium titanate, lithium niobate, lithium titanate, and/or lithium tantalate (LT). In further embodiments, both the first and second piezoelectric layers 120a and 120b includes a same material (e.g., AlN, PZT, LT, Sc, etc., or combinations thereof), but the first and second piezoelectric layers 120a and 120b differ in the concentration of the same material. Even further, the first and second piezoelectric layers may have overlapping materials and also non-overlapping materials. In one example, both the first and second piezoelectric layers 120a and 120b includes aluminum nitride, but the first and second piezoelectric layers 120a and 120b differ in the presence and/or concentration of scandium. For example, the first piezoelectric layer includes ScAlN with a chemical formula of Al_{0.93}Sc_{0.06}N and the second piezoelectric layer includes ScAlN with a chemical formula of Al_{0.7}Sc_{0.3}N.

Still referring to FIG. 6, in the embodiment shown, the second piezoelectric layer 120b is deposited such that it has an upper top horizontal surface directly above the patterned first piezoelectric layer 120a and a lower top horizontal surface directly above the second bottom electrode 106 (right bottom electrode) within the trench 170. As shown, the lower top horizontal surface is below the top surface of the patterned first piezoelectric layer 120a. This may facilitate forming a smooth sloped down topology from the first piezoelectric layer 120a to the second piezoelectric layer 120b in a later step. If the lower top horizontal surface is too high, there is risk of unwanted humps or jagged interface between the first and second piezoelectric layers 120a and 120b.

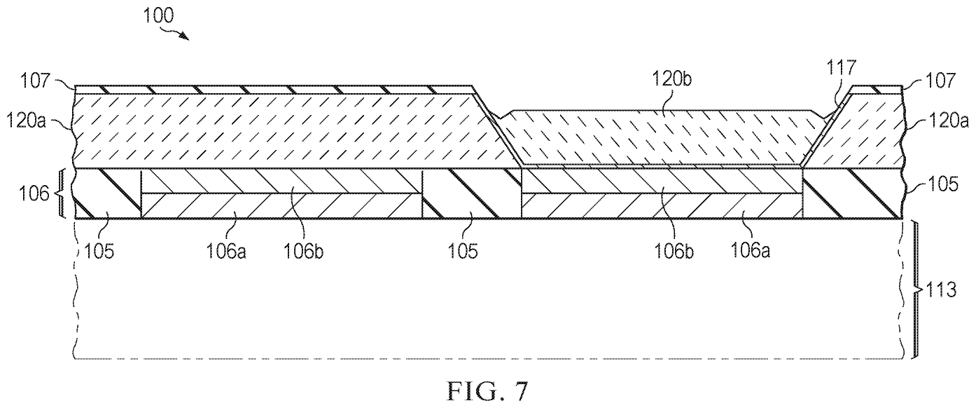

Referring now to FIG. 7, the method 200 at operation 214 selectively etches the second piezoelectric layer 120b through a patterning process. The second piezoelectric layer 120b is etched by etching portions of the second piezoelectric layer 120b over the remaining portions of the sacrificial etch stop layer 107 and etching a portion of the second piezoelectric layer 120b within the trench 170. In the embodiment shown, this etched portion within the trench 170 is etched to the lower top horizontal surface of the second piezoelectric layer 120b, where the patterned second piezoelectric layer 120b has a top surface below the top surface of the first piezoelectric layer 120a. The patterning process in operation 214 may include a lithography and/or etching process for patterning the second piezoelectric layer 120b. The etching process may include a dry etching process, a wet etching process, ion-milling, other suitable etching process, or combinations thereof. In some embodiments, the etching process is a reactive ion etching (RIE) process. Due to the etch stop layer 107 over the first piezoelectric layer 120a (when present), the first piezoelectric layer 120a is not etched when the second piezoelectric layer 120b is etched. The etch stop layer 107 provides variation uniformity across a wafer by avoiding undesired extraneous etching. As shown, the etching process may include etching until a top surface of the etch stop layer 107 is exposed, which includes etching away portions of the seed layer 117 over the etch stop layer 107. The etching completely removes portions of the second piezoelectric layer 120b directly above the horizontal top surface of the first piezoelectric layer 120a. After etching, there may be slight dips at corner portions of the patterned second piezoelectric layer 120b. In the embodiment shown, the top surface of the first piezoelectric layer 120a is above the top surface of the second piezoelectric layer 120b, and the interface therebetween includes a smooth sloped decline from the first piezoelectric layer 120a to the second piezoelectric layer 120b. In the present embodiments, the first piezoelectric layer 120a surrounds and encloses the second piezoelectric layer 120b.

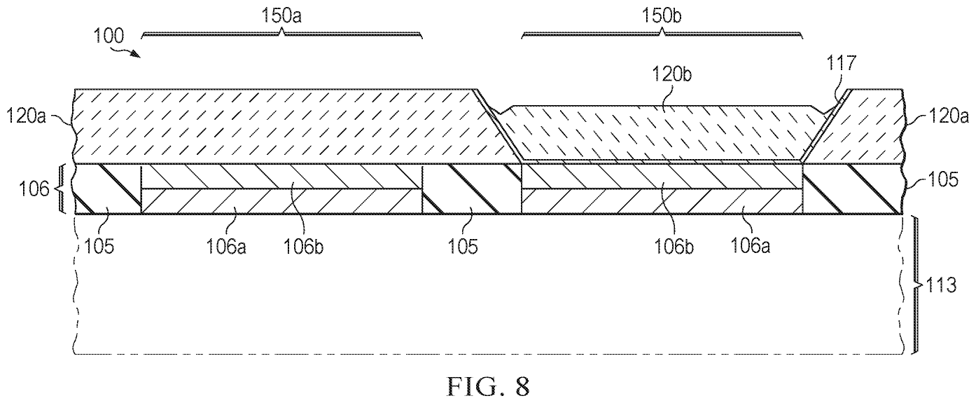

Referring now to FIG. 8, the etch stop layer 107 is then completely removed to expose the top surface of the first piezoelectric layer 120a. Additional features may be formed as part of or after the operation 214, which may include forming top electrodes 108 over respective first and second piezoelectric layers 120a and 120b and forming a passivation layer 115 over the top electrodes 108 (as shown in FIGS. 1A-1B). In the case of forming SAW devices, the top electrodes 108 may include interdigital transducer (IDT) electrodes.

Note that in the present embodiments, no planarization process (e.g., CMP) is performed to top surfaces of the patterned piezoelectric layers 120a and 120b. No CMP process is needed due to the smooth interface between the different piezoelectric materials and a substantially level top surface between the different piezoelectric layers (i.e., the patterned first piezoelectric layer 120a is only slightly higher). Further, avoiding a CMP step may save cost and improve cycle time and preserve original integrity of the piezoelectric materials. Still referring to FIG. 8, as shown, the patterned piezoelectric layers 120a and 120b having the sloped seamless interface may be portions of different resonators 150a and 150b. FIG. 9 illustrates a similar acoustic wave device 100 as the one shown in FIG. 8. The difference is that instead of having separate bottom electrodes 106 separated by the isolation structure 105, there is a shared bottom electrode 106 that extends across both resonator 150a and 150b regions.

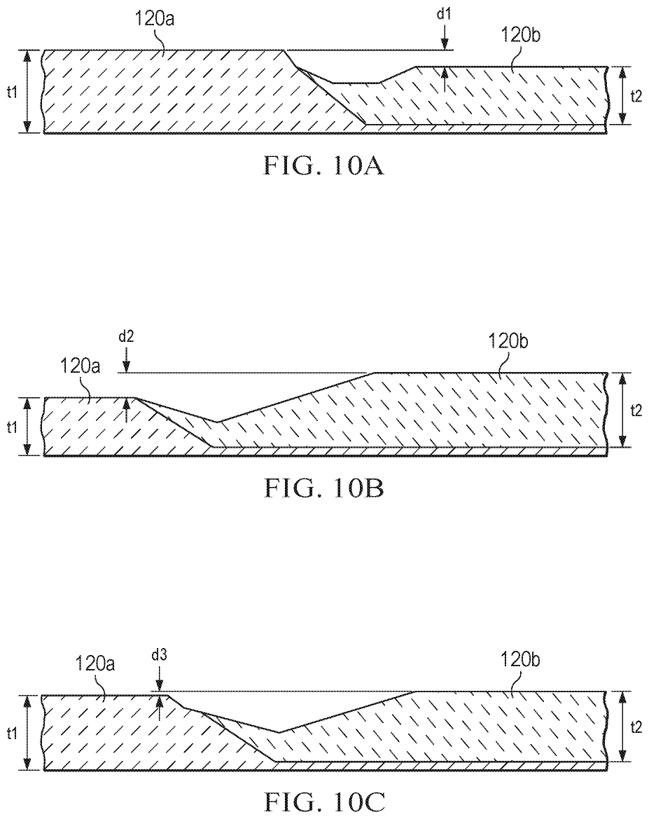

FIGS. 10A-10C illustrate various height configurations of the piezoelectric layers 120a and 120b. In all of these configurations, there is a smooth sloped interface between the piezoelectric layers 120a and 120b and a substantially level top surface between their top surfaces (i.e., there is only a slight height difference, if any). Note that FIGS. 10A-10C show the piezoelectric layer 120b landing on a thin seed layer (e.g., a seed layer having similar materials as the piezoelectric layer 120a), however in some cases the thin seed layer is omitted.

Referring now to FIG. 10A, the piezoelectric layer 120a has a thickness t1, the piezoelectric layer 120b has a thickness t2, and the top surface of the piezoelectric layer 120a is above the top surface of the piezoelectric layer 120b. This type of height configuration is previously described with respect to FIGS. 6-8. In this case, the thickness t1 of the piezoelectric layer 120a is slightly thicker than the thickness t2 of the piezoelectric layer 120b. A shown, a height difference between top surfaces of the piezoelectric layers 120a and 120b is represented by the difference d1. In an embodiment, the difference d1 is small such that it is smaller than the thickness t1 and/or the thickness t2. This limitation facilitates a substantially level top surface between the piezoelectric layers 120a and 120b, which in turn prepares for later operation steps (e.g., forming electrodes over the piezoelectric layers 120a and 120b).

Referring now to FIG. 10B, the piezoelectric layer 120a has a thickness t1, the piezoelectric layer 120b has a thickness t2, and a top surface of the piezoelectric layer 120b is above the a top surface of the piezoelectric layer 120a. In this case, the thickness t2 of the piezoelectric layer 120b is slightly thicker than the thickness t1 of the piezoelectric layer 120a. As shown, a height difference between top surfaces of the piezoelectric layers 120a and 120b is represented by the difference d2. In an embodiment, the difference d2 is small such that it is smaller than the thickness t1 and/or the thickness t2. This limitation facilitates a substantially level top surface between the piezoelectric layers 120a and 120b, which in turn prepares for later operation steps (e.g., forming electrodes over the piezoelectric layers 120a and 120b).

Referring now to FIG. 10C, the piezoelectric layer 120a has a thickness t1, the piezoelectric layer 120b has a thickness t2, and a top surface of the piezoelectric layer 120b is substantially coplanar with a top surface of the piezoelectric layer 120a. In this case, the thickness t2 of the piezoelectric layer 120b is about the same as the thickness t1 of the piezoelectric layer 120a. A height difference between top surfaces of the piezoelectric layers 120a and 120b is represented by the difference d3, which in this case is negligible. This negligible difference facilitates a substantially level top surface between the piezoelectric layers 120a and 120b, which in turn prepares for later operation steps (e.g., forming electrodes over the piezoelectric layers 120a and 120b).

Still referring to FIGS. 10A-10C, the ratio of t1 to t2 (or t2 to t1) may range from about 0.5 to about 1. In some embodiments, if the ratio is too small (e.g., smaller than 0.5) or too big (e.g., greater than 1), the height difference between the top surfaces of the piezoelectric layers 120a and 120b becomes too great. If the height difference becomes too great, abrupt humps may be formed when completing the acoustic wave device 100. These abrupt humps may lead to poorer manufacturability or device performance.

Embodiments of the present disclosure describe a smooth sloped lateral interface between different piezoelectric materials. This type of interface may also be described as a butt joint interface, where the interface is only along the lateral direction, and no portion of a first piezoelectric material layer is directly landing on a top horizontal surface of a second piezoelectric material layer (or vice versa). However, the present disclosure is not limited thereto. For example, in other embodiments, the described first and second piezoelectric layers 120a and 120b may still be formed side by side on a same die but may have a lap joint interface where a first piezoelectric material layer is directly landing on a top horizontal surface of a second piezoelectric material layer (or vice versa). In these embodiments, the cycle time may be longer and the transition between piezoelectric materials may be more abrupt and less smooth than the smooth sloped interfaces described herein. For example, a piezoelectric bump may be formed between piezoelectric materials due to one piezoelectric layer protruding and extending above an adjacent piezoelectric layer. However, even with such a bump, smaller die size is achieved with freedom to tune RF parameters. Further, the lap joint but may be improved by incorporating an etch stop layer like the etch stop layer 107 described herein. In any case, the butt joint interface may provide additional improvements over the lap joint interface due to less risk of piezo cracking, easier integration, and smoother top electrode and passivation continuity. This is because the smooth sloped interface in a butt joint interface avoids any undesired bumps or abrupt interface changes between piezoelectric materials.

Although not limiting, the present disclosure offers advantages for acoustic wave devices by integrating different piezoelectric materials laterally on a same die (e.g., butt joint interface or lap joint interface). With respect to the butt joint interface, one advantage is smoother and more leveled interface transition between piezoelectric materials. Another advantage of the present disclosure includes incorporating a sacrificial etch stop layer for uniformity improvements. Further advantages includes optimization of layout and process by leaving no trace of the sacrificial etch stop layer.

Those skilled in the art will recognize improvements and modifications to the preferred embodiments of the present disclosure. All such improvements and modifications are considered within the scope of the concepts disclosed herein and the claims that follow.

What is claimed is:

1. A method of forming an acoustic wave device, comprising:
forming a reflector stack structure over a substrate;
forming a bottom electrode over the reflector stack structure;
depositing a first piezoelectric layer over the bottom electrode;
patterning the first piezoelectric layer to form a trench exposing a top surface of the bottom electrode and a sloped side surface of the patterned first piezoelectric layer;
depositing a second piezoelectric layer in the trench and over the exposed top surface of the bottom electrode and over the first piezoelectric layer; and
patterning the second piezoelectric layer to remove portions of the second piezoelectric layer not within the trench.

2. The method of claim 1, wherein the patterned first piezoelectric layer and the patterned second piezoelectric layer interfaces each other at the sloped side surface.

3. The method of claim 1, wherein an angle between the sloped side surface and the exposed top surface of the bottom electrode is greater than about 100 degrees.

4. The method of claim 1, wherein a top horizontal surface of the patterned first piezoelectric layer is above a top horizontal surface of the patterned second piezoelectric layer.

5. The method of claim 1, wherein before the patterning of the first piezoelectric layer, further comprising:
depositing an etch stop layer over the first piezoelectric layer, wherein the patterning of the first piezoelectric layer includes etching through a portion of the etch stop layer to form the trench.

6. The method of claim 5,
wherein after the depositing of the second piezoelectric layer, portions of the second piezoelectric layer is disposed over remaining portions of the etch stop layer,
wherein the patterning of the second piezoelectric layer includes etching the portions of the second piezoelectric layer disposed over the remaining portions of the etch stop layer.

7. The method of claim 6, further comprising:
completely removing the etch stop layer; and
forming a top electrode over the patterned first and second piezoelectric layers.

8. The method of claim 1, wherein the first piezoelectric layer and the second piezoelectric layer include different materials.

9. The method of claim 1,
wherein the first piezoelectric layer and the second piezoelectric layer both include aluminum nitride,
wherein the first piezoelectric layer has a first concentration of scandium, the second piezoelectric layer has a second concentration of scandium, and the second concentration is different from the first concentration.

10. The method of claim 1, wherein before the depositing the second piezoelectric layer, further comprising:
depositing a seed layer in the trench, wherein the seed layer directly lands on the exposed top surface of the bottom electrode and directly lands on the sloped side surface of the patterned first piezoelectric layer,
wherein the second piezoelectric layer is deposited directly on the seed layer.

11. The method of claim 10, wherein the seed layer and the first piezoelectric layer include the same materials.

12. The method of claim 1,
wherein the bottom electrode includes a first portion and a second portion, and the exposed top surface of the bottom electrode is a top surface of the second portion,
wherein the first piezoelectric layer is directly above the first portion, the second piezoelectric layer is directly above the second portion, and the first and second portions are separated from each other by an isolation structure.

13. A method of forming an acoustic wave device, comprising:
forming a reflector stack structure over a substrate;
forming first and second bottom electrodes over the reflector stack structure, wherein the first and second bottom electrodes are separated by an isolation structure;
depositing a first piezoelectric layer over the first and the second bottom electrodes;
depositing a sacrificial etch stop layer over the first piezoelectric layer;
selectively etching the first piezoelectric layer by etching through the etch stop layer to form a trench exposing a top surface of the second bottom electrode;
depositing a second piezoelectric layer in the trench and over remaining portions of the sacrificial etch stop layer; and
selectively etching the second piezoelectric layer by etching portions of the second piezoelectric layer over the remaining portions of the sacrificial etch stop layer.

14. The method of claim 13, after the selectively etching of the second piezoelectric layer, further comprising:
completely removing the sacrificial etch stop layer; and
forming a first top electrode over the first piezoelectric layer and a second top electrode over the second piezoelectric layer.

15. The method of claim 13, wherein the sacrificial etch stop layer is a metal layer.

16. The method of claim 13, wherein before the depositing the second piezoelectric layer, further comprising:
depositing a seed layer on the remaining portions of the etch stop layer and on the top surface of the second bottom electrode,
wherein the second piezoelectric layer is deposited directly on the seed layer.

17. The method of claim 16, wherein the selectively etching of the second piezoelectric layer includes etching portions of the seed layer disposed directly on the sacrificial etch stop layer.

18. A piezoelectric device, comprising:
a reflector stack structure over a substrate;
a bottom electrode over the reflector stack structure;
a first piezoelectric layer landing on a first portion of the bottom electrode; and
a second piezoelectric layer landing on a second portion of the bottom electrode,
wherein the first piezoelectric layer and the second piezoelectric layer include different piezoelectric materials,
wherein the first piezoelectric layer and the second piezoelectric layer are laterally adjacent to each other and share a sloped interface.

19. The piezoelectric device of claim 18, wherein an angle between the sloped interface and a top surface of the second portion of the bottom electrode is greater than about 100 degrees.

20. The piezoelectric device of claim 18, wherein a top horizontal surface of the first piezoelectric layer is above a top horizontal surface of the second piezoelectric layer.
